(19) United States
(12) Patent Application Publication
(10) Pub. No.: US 2011/0175142 A1
(43) Pub. Date: Jul. 21, 2011

(54) NITRIDE SEMICONDUCTOR DEVICE

(75) Inventors: Naohiro Tsurumi, Kyoto (JP); Satoshi Nakazawa, Osaka (JP); Tetsuzo Ueda, Osaka (JP)

(73) Assignee: PANASONIC CORPORATION, Osaka (JP)

(21) Appl. No.: 13/120,382

(22) PCT Filed: Aug. 26, 2009
(86) PCT No.: PCT/JP2009/004125

§ 371 Date: Mar. 22, 2011

(30) Foreign Application Priority Data
Oct. 22, 2008 (JP) 2008-272007

(51) Int. Cl. H01L 29/80

(52) U.S. Cl. 257/192; 257/E29.31

(57) ABSTRACT

A nitride semiconductor device includes a first nitride semiconductor layer; a second nitride semiconductor layer formed on the first nitride semiconductor layer, and having a wider bad gap than the first nitride semiconductor layer; a source electrode, a drain electrode, and a gate electrode, which are formed on the second nitride semiconductor layer; a high resistive layer formed lower than the first nitride semiconductor layer; a conductive layer formed under and in contact with the high resistive layer; a lower insulating layer formed under the conductive layer; and a bias terminal electrically connected to the conductive layer.

### TECHNICAL FIELD

The present invention relates to nitride semiconductor devices, and more particularly to nitride semiconductor devices used in high frequency applications.

### BACKGROUND ART

Group III-V nitride semiconductors such as compounds of gallium nitride (GaN), aluminum nitride (AlN), and indium nitride (InN), which are represented by the general formula of AlₓGa_{1-x-y}In_{y}N (where 0≦x≦1, and 0≦y≦1), have wide band gaps and direct transition band structures. Utilizing these features, applications of the semiconductors to short wavelength optical elements have been considered. Furthermore, since the semiconductors have the features of high breakdown electric fields and saturated electron velocity, applications of the semiconductors to high output and high speed electronic devices have been considered.

Two-dimensional electron gas (hereinafter referred to as 2 DEG) is formed at the interface between an AlₓGa_{1-x-y}Nₓ layer (where 0≦x≦1) and a GaN layer, which are sequentially epitaxially grown on a semi-insulating substrate. The 2 DEG is spatially separated from donor impurities added into the AlGaN layer, and thus, has high electron mobility. Furthermore, so-called “saturated drift velocity” is high in GaN materials. For example, in a high electric field region of about 1×10⁵ V/cm, GaN materials have electron velocity twice or more as high as that of GaAs materials, which are now in the market as materials for high frequency transistors. Therefore, applications of heterojunction field effect transistors (hereinafter referred to as HFETs) utilizing 2 DEG to high frequency and high output devices are expected.

In order to obtain a high performance HFET, a nitride semiconductor having excellent crystallinity needs to be grown on a substrate. To improve the crystallinity of the nitride semiconductor, a substrate, which is lattice-matched to the nitride semiconductor, is preferably used. Thus, the substrate made of a material such as silicon carbide (SiC) and sapphire is used as a substrate, on which a nitride semiconductor is grown. However, SiC substrates and sapphire substrates are expensive. In addition, if a back surface electrode is formed on a back surface of the substrate, a via hole penetrating the substrate is needed. In this case, the substrate needs to be polished to be thin. However, damages are easily caused by polishing, since the SiC substrate or the sapphire substrate is fragile. In order to avoid these problems, growing a nitride semiconductor on a silicon (Si) substrate is actively researched. At present, a nitride semiconductor, which has slightly poorer crystallinity than that grown on a SiC substrate but has crystallinity sufficiently high in practical use, can be grown on a Si substrate (see, e.g., Non-Patent Document 1).

### CITATION LIST

### Non-Patent Document

NON-PATENT DOCUMENT 1: Masumi Fukuda and Yasutake Hirachi, Basis for GaAs Field Effect Transistor, J. IEIE Jpn., p. 214 (1992)

### SUMMARY OF THE INVENTION

### Technical Problem

However, the present inventors found that, if a Si substrate is used as a substrate for a nitride semiconductor device, there arise the following problems other than the crystallinity of the nitride semiconductor device.

A Si substrate has lower resistance than a SiC substrate. This causes loss of high frequency components when using the nitride semiconductor device in high frequency applications. Furthermore, carriers remain at the interface between the Si substrate and an epitaxially grown layer, thereby causing loss of high frequency components caused by the carriers remaining at the interface. The interface retaining carriers may occur also when using a substrate other than a Si substrate.

It is an objective of the present disclosure to solve the above problems and realize a nitride semiconductor device with reduced loss of high frequency components caused by carriers remaining at an interface located lower than a channel layer.

### Solution to the Problem

In order to achieve the objective, the present disclosure provides a nitride semiconductor device, in which a bias voltage is applied to a high resistive layer formed lower than a channel layer.

Specifically, an example nitride semiconductor device includes a lower insulating layer; a conductive layer provided on the lower insulating layer; a high resistive layer provided on the conductive layer; a first nitride semiconductor layer provided on the high resistive layer; a second nitride semiconductor layer provided on the first nitride semiconductor layer, and having a wider band gap than the first nitride semiconductor layer; a source electrode, a drain electrode, and a gate electrode, which are provided on the second nitride semiconductor layer; and a bias terminal electrically connected to the conductive layer.

The example nitride semiconductor device includes the high resistive layer and the conductive layer at lower positions than the first nitride semiconductor layer. Thus, even if an interface retaining carriers is formed lower than the first nitride semiconductor layer, the carriers can be allowed to flow by applying a bias voltage to the conductive layer. Therefore, it is possible to realize a nitride semiconductor device with reduced loss of high frequency components caused by the carriers remaining at the interface, and with excellent frequency characteristics.

In the example nitride semiconductor device, the high resistive layer may be a silicon substrate. The conductive layer may be formed on a back surface of the silicon substrate. The lower insulating layer may be an insulating holding substrate bonded to a back surface side of the silicon substrate with the conductive layer interposed therebetween.

In this case, the device may further include a back surface electrode formed on a back surface of the holding substrate.

In the example nitride semiconductor device, the lower insulating layer may be a buried insulating layer of an SOI substrate including a supporting layer, the buried insulating layer, and an active layer. The conductive layer may be the active layer. The high resistive layer may be a third nitride semiconductor layer formed on the SOI substrate.

In this case, the device may further include a back surface electrode formed on a back surface of the SOI substrate.

In the example nitride semiconductor device, the lower insulating layer may be an insulating element formation substrate. The conductive layer may be a conductive nitride semiconductor layer formed on the element formation substrate. The high resistive layer may be a third nitride semiconductor layer formed on the conductive nitride semiconductor layer.

In this case, the device may further include a back surface electrode formed on a back surface of the element formation substrate.

The example nitride semiconductor device may further include an upper insulating layer formed on the second nitride semiconductor layer, and covering the source electrode, the drain electrode and the gate electrode. The bias terminal may be an electrode pad formed on the upper insulating layer. The electrode pad and the conductive layer may be electrically connected together by a plug penetrating the upper insulating layer, the second nitride semiconductor layer, the first nitride semiconductor layer, and the high resistive layer.

In the example nitride semiconductor device, the bias terminal may be an electrode pad formed in a region of the holding substrate, which is not covered with the silicon substrate.

In the example nitride semiconductor device, the back surface electrode may be electrically connected to the source electrode.

### Advantages of the Invention

The example nitride semiconductor device realizes a nitride semiconductor device with reduced loss of high frequency components caused by carriers remaining at the interface located lower than a channel layer.

### BRIEF DESCRIPTION OF THE DRAWINGS

FIG. 1 is a cross-sectional view illustrating a nitride semiconductor device according to a first embodiment.

FIG. 2 is an equivalent circuit schematic of the nitride semiconductor device according to the first embodiment.

FIG. 3 is a graph illustrating output characteristics of the nitride semiconductor device according to the first embodiment.

FIG. 4 is a cross-sectional view illustrating an example variation of the nitride semiconductor device according to the first embodiment.

FIG. 5 is a cross-sectional view illustrating an example variation of the nitride semiconductor device according to the first embodiment.

FIG. 6 is a cross-sectional view illustrating a nitride semiconductor device according to a second embodiment.

FIG. 7 is a cross-sectional view illustrating a nitride semiconductor device according to a third embodiment.

### DESCRIPTION OF EMBODIMENTS

### First Embodiment

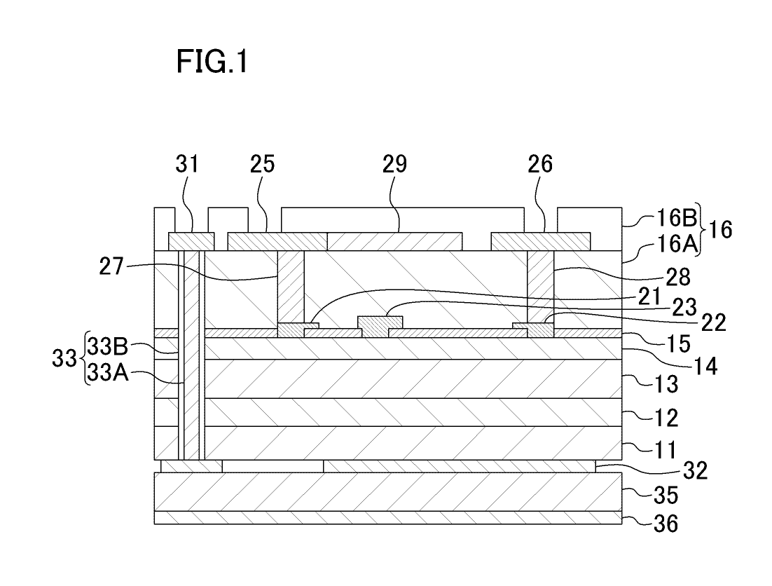

A first embodiment will be described hereinafter with reference to the drawings. FIG. 1 illustrates a cross-sectional structure of a nitride semiconductor device according to the first embodiment. The nitride semiconductor device of the first embodiment is basically an HFET formed on a Si substrate. A channel layer 13 of GaN with a thickness of 1000 nm, and a Schottky layer 14 of n-type AlₓGa₁₋ₓN (where 0<x≦1) with a thickness of 25 nm are sequentially formed on a Si substrate 11 with a thickness of 500 μm, with a buffer layer 12 interposed therebetween. The buffer layer 12 is provided to reduce the lattice mismatch among the Si substrate 11, the channel layer 13, and the Schottky layer 14; and may be made of high resistive Al_{y}Ga_{1-y}N (where 0<y≦1) with a thickness of 500 nm. A channel made of 2 DEG is formed near the interface of the channel layer 13 with the Schottky layer 14.

A source electrode 21 and a drain electrode 22 are formed on the Schottky layer 14, and the source electrode 21 and the drain electrode 22 are in ohmic contact with the channel. A gate electrode 23 is formed between the source electrode 21 and the drain electrode 22. Each of the source electrode 21 and the drain electrode 22 may be a multilayer of titanium (Ti) and aluminum (Al) with a thickness of 200 nm. The gate electrode 23 may be a multilayer of nickel (Ni) and gold (Au) with a thickness of 400 nm.

The Schottky layer 14 is covered by a protective film 15 of silicon nitride (SiN) with a thickness of 100 nm, except for the region provided with the source electrode 21, the drain electrode 22, and the gate electrode 23. An upper insulating layer 16 is formed on the protective film 15 to cover the source electrode 21, the drain electrode 22, and the gate electrode 23. The upper insulating layer 16 is formed by stacking a first insulating film 16A and a second insulating film 16B. A source electrode pad 25 connected to the source electrode 21 by a first plug 27, a drain electrode pad 26 connected to the drain electrode by a second plug 28, and an interconnection 29 are formed on the first insulating film 16A. A gate electrode pad (not shown) connected to the gate electrode 23 may be formed as necessary. Furthermore, a bias electrode pad 31 is formed, which is a bias terminal applying a bias voltage to a conductive layer 32, which is described below.

The Si substrate 11 of this embodiment is a high-resistive substrate. The term “high-resistive” as used here means that no current flows during normal operation of the HFET, and includes a so-called semi-insulating state. The specific resistance changes depending on the characteristics of the HFET to be formed, but may range from about 1KΩcm to about 10MΩcm.

The high resistive Si substrate has sufficiently high resistance to a direct current component, thereby not allowing a leakage current to flow. However, since the substrate does not have perfect insulating properties, a leakage current can flow when signals are high frequency components, thereby causing loss of the high frequency components.

Furthermore, the present inventors found that carriers remain at the interface between the high resistive Si substrate and the nitride semiconductor layer. Since the carriers remain at the interface, the Si substrate functions as a capacitor, thereby causing loss of the high frequency components.

The reason is unclear why the carriers remain at the interface between the Si substrate and the nitride semiconductor layer. One possible reason is that Al or the like is diffused into the Si substrate when growing the nitride semiconductor. In order to reduce effects of the carriers remaining at the interface between the Si substrate and the nitride semiconductor layer, there may be a method of applying a voltage from the outside of the interface between the Si substrate and the nitride semiconductor layer.

In the first embodiment, the carriers remaining at the interface between the Si substrate and the nitride semiconductor layer are allowed to flow by applying a bias voltage to the back surface of the Si substrate 11. As a basic structure, a conductive layer may be formed, which applies a bias voltage in contact with the surface of the high resistive layer, which is opposite to the channel.

Specifically, the conductive layer 32 for applying a bias voltage to the back surface of the Si substrate 11, which is a high resistive layer. The conductive layer 32 may be, for example, a multilayer of Ti and Au. The conductive layer 32 is electrically connected to the bias electrode pad 31 formed on the upper insulating layer 16 by a third plug 33. The third plug 33 includes a conductive body 33A and an insulating film 33B, which penetrate the upper insulating layer 16, the protective film 15, the Schottky layer 14, the channel layer 13, the buffer layer 12, and the Si substrate 11; and is electrically isolated from the 2 DEG.

If the conductive layer 32 is exposed to the bottom surface of the semiconductor device, the semiconductor device is difficult to mount. In this embodiment, an insulating holding substrate 35 is provided under the conductive layer 32 as a lower insulating layer. Specifically, the Si substrate 11 including the conductive layer 32 on the back surface is held on the holding substrate 35. A back surface electrode 36 of a multilayer of chrome (Cr) and gold (Au) is formed on the back surface of the holding substrate 35.

The semiconductor device of the first embodiment allows the carriers remaining at the interface between the Si substrate and the nitride semiconductor layer to flow by applying a voltage to the bias electrode pad 31. Therefore, loss of the high frequency components can be reduced, thereby improving the high frequency characteristics.

The detail of the bias voltage applied to the conductive layer 32 will be described later.

By holding the Si substrate 11 with the conductive layer 32 on the holding substrate 35, the present device can be mounted similarly to a conventional semiconductor device. The holding substrate 35 may be a ceramic substrate or a resin substrate, and may be bonded to the Si substrate 11 with the conductive layer 32 interposed therebetween.

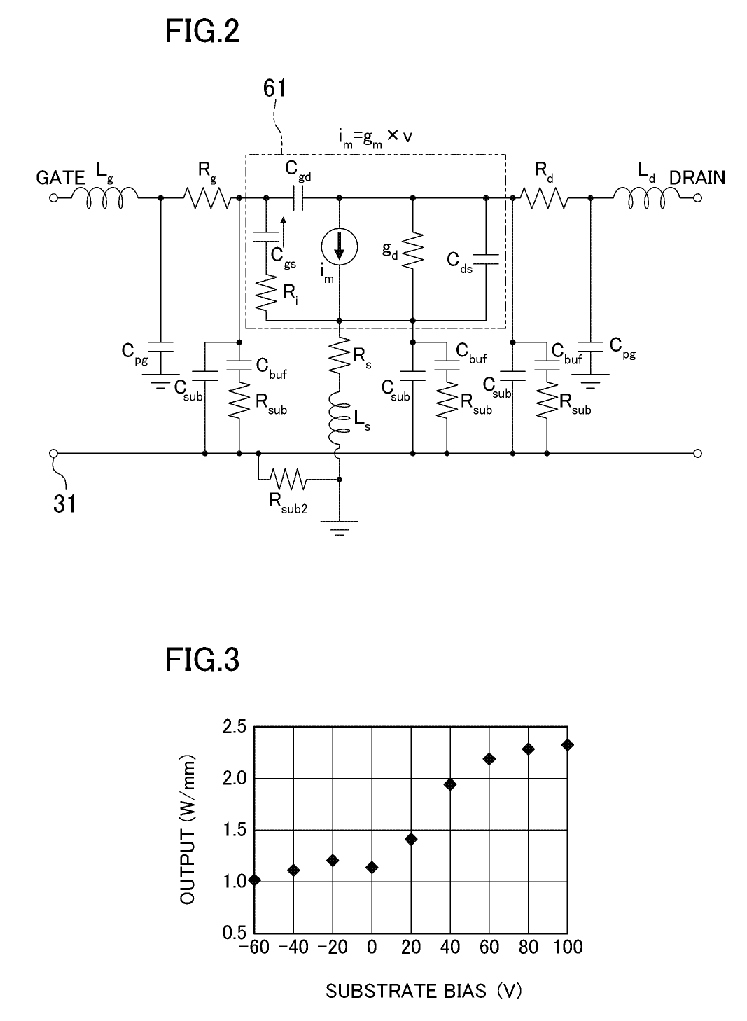

FIG. 2 illustrates the semiconductor device of the first embodiment as an equivalent circuit. The drain resistance is represented by g_{d}, the resistance component of the Si substrate 11 is represented by R_{sub}, the capacitance component of the Si substrate 11 is represented by C_{sub}, and the capacitance component of the buffer layer 12 is represented by C_{buf}. When a substrate bias is applied to the bias electrode pad 31 at the time when applying a high frequency to the semiconductor device, C_{buf} becomes conductive. With this feature, the resistance component of an intrinsic region 61 becomes 1/(g_{d}+R_{sub}), thereby increasing the substantial resistance component. This increases the output resistance, and reduces the drain conductance, thereby reducing loss of high frequency signals.

In FIG. 2, Rᵢ represents the resistance at the intrinsic region, and R_{sub2} represents the resistance at the holding substrate 35. C_{gd} represents the gate-drain capacitance, C_{gs} represents the gate-source capacitance, and C_{ds} represents the drain-source capacitance. R_{g}, Rₛ, and R_{d} represent the interconnect resistance of the gate, the source, and the drain. L_{g}, Lₛ, and L_{d} represent the parasitic inductance of the gate, the source, and the drain. C_{pg} represents the parasitic inductance of the package.

FIG. 3 illustrates output characteristics when changing the substrate bias applied to the semiconductor device of the first embodiment. In FIG. 3, the vertical axis represents an output, and the horizontal axis represents a substrate bias. As shown in FIG. 3, the output is doubled by applying a positive substrate bias. Note that the polarity of the substrate bias needs to be selected depending on whether the carriers remaining at the interface between the substrate and the nitride semiconductor layer are electrons or holes.

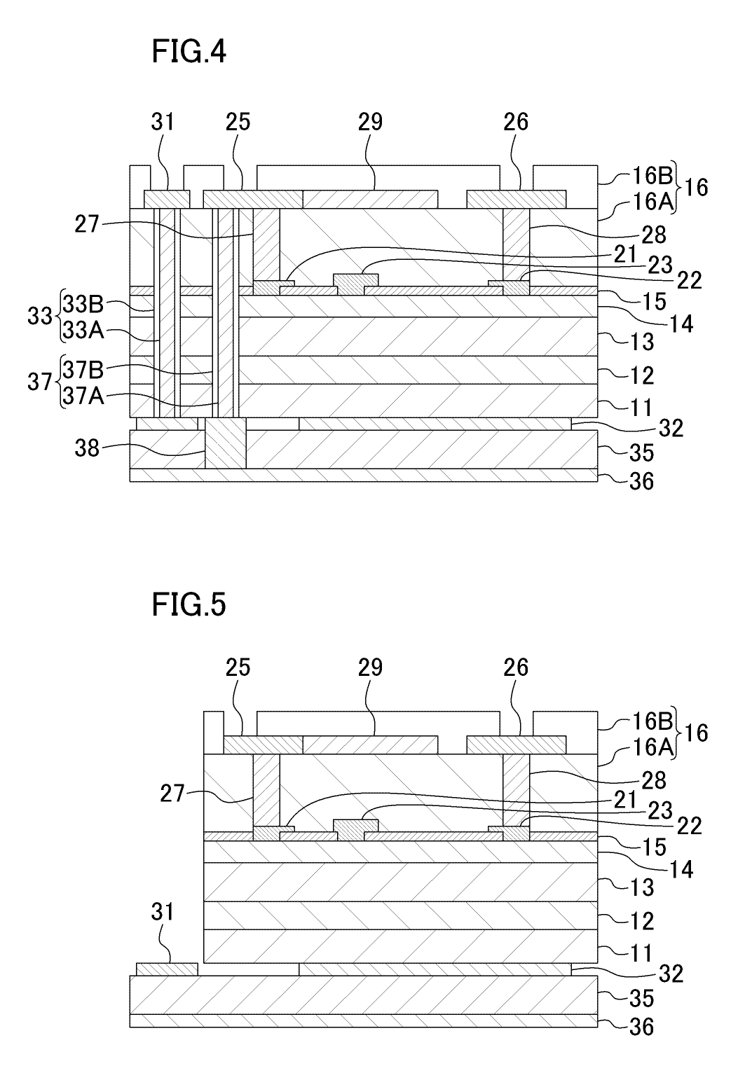

In this embodiment, as shown in FIG. 4, the back surface electrode 36 may be electrically connected to the source electrode pad 25. This facilitates supply of ground potential to the source electrode 21. The back surface electrode 36 may be connected to the source electrode pad 25 by a substrate penetrating plug 38 penetrating the holding substrate 35, and by a fourth plug 37 penetrating the upper insulating layer 16, the protective film 15, the Schottky layer 14, the channel layer 13, the buffer layer 12, and the Si substrate 11. The fourth plug 37 includes a conductive body 37A and an insulating film 37B, and is electrically isolated from the 2 DEG.

Furthermore, while the bias electrode pad 31 is formed on the upper insulating layer 16, it may be formed on the holding substrate 35, as shown in FIG. 5. Any structure is possible, as long as a bias voltage can be applied to the conductive layer 32.

### Second Embodiment

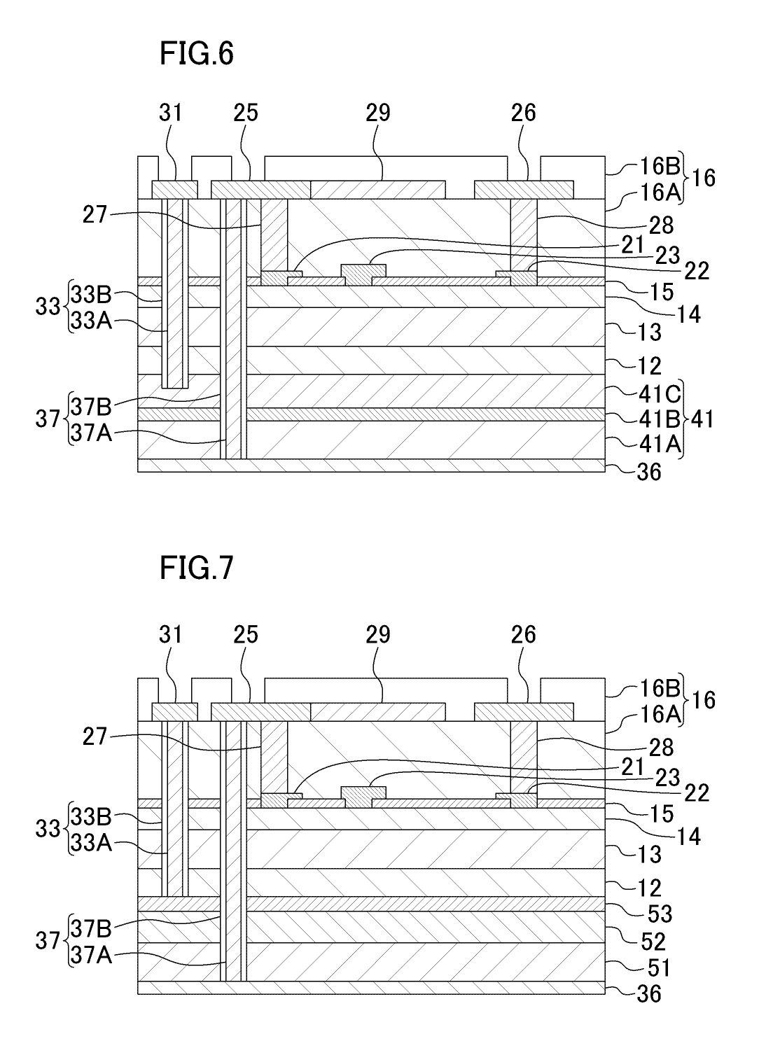

A second embodiment will be described hereinafter with reference to the drawing. FIG. 6 illustrates a cross-sectional structure of a nitride semiconductor device according to the second embodiment. In FIG. 6, the same reference characters as those shown in FIG. 1 are used to represent equivalent elements, and the explanation thereof will be omitted.

As shown in FIG. 6, the nitride semiconductor device of the second embodiment is an HFET formed on a silicon-on-insulator (SOI) substrate 41. A buffer layer 12, a channel layer 13, and a Schottky layer 14 are sequentially formed on the SOI substrate 41 including a supporting layer 41A, a buried insulating layer 41B, and a conductive active layer 41C. A bias electrode pad 31 formed on an upper insulating layer 16 is connected to the active layer 41C via a third plug 33.

In the semiconductor device of the second embodiment, the active layer 41C functions as a conductive layer for applying a bias voltage, and the buffer layer 12 functions as a high resistive layer provided between the channel layer and the conductive layer.

The semiconductor device of this embodiment is easily formed, since there is no need to bond the holding substrate. The SOI substrate 41 may be formed by bonding together, or by separation by implantation of oxygen (SIMOX).

### Third Embodiment

A third embodiment will be described hereinafter with reference to the drawing. FIG. 7 illustrates a cross-sectional structure of a nitride semiconductor device according to the third embodiment. In FIG. 7, the same reference characters as those shown in FIG. 1 are used to represent equivalent elements, and the explanation thereof will be omitted.

As shown in FIG. 7, the nitride semiconductor device of the third embodiment is an HFET formed on an insulating substrate 51. A conductive semiconductor layer 53 is formed on the insulating substrate 51 with a buffer layer 52 interposed therebetween. A high resistive buffer layer 12, a channel layer 13, and a Schottky layer 14 are sequentially formed on the conductive semiconductor layer 53. A bias electrode pad 31 formed on an upper insulating layer 16 is connected to the conductive semiconductor layer 53 via a third plug 33.

In the semiconductor device of the third embodiment, the conductive semiconductor layer 53 functions as a conductive layer for applying a bias voltage, and the buffer layer 12 functions as a high resistive layer provided between the channel layer and the conductive layer.

In the third embodiment, a substrate, which is likely to be lattice matched with a nitride semiconductor such as sapphire or SiC, may be used as the insulating substrate 51. The conductive semiconductor layer 53 may be a nitride semiconductor layer formed by epitaxial growth, and may be made of Al_{z}Ga_{1-z}N (where 0<z≦1) doped with n-type impurities. Note that the layer may be made of other materials as long as it is conductive, and may be doped with p-type impurities.

If an insulating substrate is made of sapphire, SiC, or the like, loss of high frequency components caused by current flowing into the substrate itself does not occur. However, the interface retaining carriers can occur within the nitride semiconductor layer. With the structure of the third embodiment, since the carriers remaining at the interface are allowed to flow, thereby improving the characteristics of the nitride semiconductor device.

In this embodiment, the term “bias terminal” means a terminal electrically connected to the conductive layer to apply a voltage different from reference (ground) potential to the conductive layer.

In each embodiment, the substrate bias applied to the conductive layer 32 is applied between the layer and the reference (ground) potential. Thus, the conductive layer 32 and the bias electrode pad 31 electrically connected to the conductive layer 32 should not be directly connected to ground during the operation of the semiconductor device. That is, the bias electrode pad 31 needs to be independent from at least one of the source electrode 21 and the drain electrode, which is connected to ground (i.e., should not be short-circuited to one of the source electrode 21 and the drain electrode, which is connected to ground). As long as a voltage can be applied between the conductive layer 32 and ground, the terminal is not necessarily in the form of a pad.

### INDUSTRIAL APPLICABILITY

The example nitride semiconductor device realizes a nitride semiconductor device with reduced loss of high frequency components caused by carriers remaining at the interface lower than a channel layer, and is thus, useful as a nitride semiconductor device, particularly in high frequency applications and the like.

### DESCRIPTION OF REFERENCE CHARACTERS

11 Si Substrate
12 Buffer Layer
13 Channel Layer
14 Schottky Layer
15 Protective Film
16 Upper Insulating Layer
16A First Insulating Film
16B Second Insulating Film
21 Source Electrode
22 Drain Electrode
23 Gate Electrode
25 Source Electrode Pad
26 Drain Electrode Pad
27 First Plug
28 Second Plug
29 Interconnection
31 Bias Electrode Pad
32 Conductive Layer
33 Third Plug
35 Holding Substrate
36 Back Surface Electrode
37 Fourth Plug
41 SOI Substrate
41A Supporting Layer
41B Buried Insulating Layer
41C Active Layer
51 Insulating Substrate
52 Buffer Layer
53 Conductive Semiconductor Layer
61 Intrinsic Region

1. A nitride semiconductor device comprising:
a lower insulating layer;
a conductive layer provided on the lower insulating layer;
a high resistive layer provided on the conductive layer;
a first nitride semiconductor layer provided on the high resistive layer;
a second nitride semiconductor layer provided on the first nitride semiconductor layer, and having a wider band gap than the first nitride semiconductor layer;
a source electrode, a drain electrode, and a gate electrode, which are provided on the second nitride semiconductor layer; and
a bias terminal electrically connected to the conductive layer.

2. The nitride semiconductor device of claim 1, wherein
the high resistive layer is a silicon substrate,
the conductive layer is formed on a back surface of the silicon substrate, and
the lower insulating layer is an insulating holding substrate bonded to a back surface side of the silicon substrate with the conductive layer interposed therebetween.

3. The nitride semiconductor device of claim 2, wherein
the bias terminal is an electrode pad formed in a region of the holding substrate, which is not covered with the silicon substrate.

4. The nitride semiconductor device of claim 2, further comprising
a back surface electrode formed on a back surface of the holding substrate.

5. The nitride semiconductor device of claim 4, wherein
the back surface electrode is electrically connected to the source electrode.

6. The nitride semiconductor device of claim 1, wherein
the lower insulating layer is a buried insulating layer of an SOI substrate including a supporting layer, the buried insulating layer, and an active layer,
the conductive layer is the active layer, and
the high resistive layer is a third nitride semiconductor layer formed on the SOI substrate.

7. The nitride semiconductor device of claim 6, further comprising
a back surface electrode formed on a back surface of the SOI substrate.

8. The nitride semiconductor device of claim 7, wherein
the back surface electrode is electrically connected to the source electrode.

9. The nitride semiconductor device of claim 1, wherein
the lower insulating layer is an insulating element formation substrate,
the conductive layer is a conductive nitride semiconductor layer formed on the element formation substrate, and
the high resistive layer is a third nitride semiconductor layer formed on the conductive nitride semiconductor layer.

10. The nitride semiconductor device of claim 9, further comprising
a back surface electrode formed on a back surface of the element formation substrate.

11. The nitride semiconductor device of claim 10, wherein
the back surface electrode is electrically connected to the source electrode.

12. The nitride semiconductor device of claim 1, further comprising
an upper insulating layer formed on the second nitride semiconductor layer, and covering the source electrode, the drain electrode and the gate electrode, wherein
the bias terminal is an electrode pad formed on the upper insulating layer, and
the electrode pad and the conductive layer are electrically connected together by a plug penetrating the upper insulating layer, the second nitride semiconductor layer, the first nitride semiconductor layer, and the high resistive layer.
